(19) United States
(12) Patent Application Publication
(10) Pub. No.: US 2013/0285201 A1
(43) Pub. Date: Oct. 31, 2013

(54) MIM CAPACITOR FORMATION METHOD AND STRUCTURE

(71) Applicants: Zhihong Zhang, Chandler, AZ (US); Xu Cheng, Chandler, AZ (US); Todd C. Roggenbauer, Austin, TX (US); Jiang-Kai Zuo, Chandler, AZ (US)

(72) Inventors: Zhihong Zhang, Chandler, AZ (US); Xu Cheng, Chandler, AZ (US); Todd C. Roggenbauer, Austin, TX (US); Jiang-Kai Zuo, Chandler, AZ (US)

(73) Assignee: FREESCALE SEMICONDUCTOR, INC., Austin, TX (US)

(21) Appl. No.: 13/458,947

(22) Filed: Apr. 27, 2012

(51) Int. Cl. H01L 29/02; H01L 21/02

(52) U.S. Cl. 257/532; 438/381; 257/E21.008; 257/E29.002

(57) ABSTRACT

Metal-insulator metal (MIM) capacitors are formed by providing a substrate having a first surface, forming thereon a first electrode having conductive and insulating regions wherein the conductive regions desirably have an area density D_{A} less than 100%. A first dielectric is formed over the first electrode. A cavity is formed in the first dielectric, having a sidewall extending to the first electrode and exposing thereon some of the first electrode conductive and insulating regions. An electrically conductive barrier layer is formed covering the sidewall and the some of the first electrode conductive and insulating regions. A capacitor dielectric layer is formed in the cavity covering the barrier layer. A counter electrode is formed in the cavity covering the capacitor dielectric layer. External connections are formed to a portion of the first electrode laterally outside the cavity and to the counter electrode within the cavity.

### FIELD OF THE INVENTION

This invention relates generally to methods and structures for metal-insulator-metal (MIM) capacitors, especially MIM capacitors for use in integrated circuits (ICs).

### BACKGROUND OF THE INVENTION

Capacitors are common elements much used in electronic circuits. Capacitors for use in integrated circuits (ICs) may be fabricated in various forms. For example, PN junctions and metal-semiconductor (SC) junctions, in addition to providing rectifying action, may also serve as capacitive elements in ICs. However, such elements are not symmetrically bi-lateral and are not suitable in many applications. There is a need for reliable and space efficient symmetrical capacitive elements, such as those provided by metal-insulator-metal (MIM) structures. However the ability to incorporate MIM capacitors within a particular IC can depend on many factors, as for example but not intended to be limiting, the attainable capacitance per unit area, the compatibility of the MIM capacitor fabrication materials, process and geometry with the overall IC fabrication materials, process and geometry, the additional expense associated with incorporating such MIM capacitor(s) within a particular IC, the attainable Q, the breakdown voltage, the leakage current and the reliability of particular MIM capacitor configurations and materials, and so forth. Such considerations are usually complex and often interact negatively so that desirable choices for optimizing the capacitor(s) may adversely impact other portions of the IC and its manufacture. Hence, there is an ongoing need for fabrication methods and structures for MIM capacitors that minimize or avoid such negative interactions, that are compatible with IC manufacturing processes, that add minimum additional expense and that provide capacitors having useful electrical properties.

### BRIEF DESCRIPTION OF THE DRAWINGS

The invention will be better understood from a reading of the following detailed description, taken in conjunction with the accompanying figures in the drawings in which like numerals denote like or analogous elements, and wherein:

FIG. 1 shows a simplified schematic cross-sectional views of a metal-insulator-metal (MIM) capacitor, according to an embodiment of the invention;

FIGS. 2-4 show plan views of illustrative lower electrode structures of the MIM capacitor of FIG. 1, according to further embodiments of the invention;

FIGS. 5-13 show simplified cross-sectional views of the capacitor of FIGS. 1-4 at various stages of manufacture illustrating the structures formed in such manufacturing stages, according to still further embodiments of the invention; and

FIG. 14 illustrates a flow chart for a method of manufacturing an MIM capacitor as a part of an IC, according to yet further embodiments of the invention.

### DETAILED DESCRIPTION OF THE INVENTION

The following detailed description is merely exemplary in nature and is not intended to limit the invention or the application and uses of the invention. Furthermore, there is no intention to be bound by any expressed or implied theory presented in the preceding technical field, background, or the following detailed description.

For simplicity and clarity of illustration, the drawing figures illustrate the general manner of construction and/or manufacture, and descriptions and details of well-known features and techniques may be omitted to avoid unnecessarily obscuring the invention. Additionally, elements in the drawings figures are not necessarily drawn to scale. For example, the dimensions of some of the elements or regions in the figures may be exaggerated relative to other elements or regions to help improve understanding of embodiments of the invention.

The terms “first,” “second,” “third,” “fourth” and the like in the description and the claims, if any, may be used for distinguishing between somewhat similar elements and/or manufacturing steps and not necessarily for describing a particular spatial arrangement or sequence or chronological order. It is to be understood that the terms so used are interchangeable under appropriate circumstances such that embodiments of the invention described herein are, for example, capable of operation or construction in sequences, orientations and arrangements other than those illustrated or otherwise described herein. Furthermore, the terms “comprise,” “include,” “have” and any variations thereof, are intended to cover non-exclusive inclusions, such that a process, method, article, or apparatus that comprises a list of elements is not necessarily limited to those elements, but may include other elements or steps not expressly listed or inherent to such process, method, article, or apparatus. The term “coupled,” as used herein, is defined as directly or indirectly connected in an electrical or non-electrical manner. As used herein the terms “substantial” and “substantially” mean sufficient to accomplish the stated purpose in a practical manner and that minor imperfections, if any, are not significant for the stated purpose. Further, unless otherwise particularly noted, as used herein the term “metal” is intended to include any type of material possessing significant electrical conductivity, including but not limited to metallic elements, semimetals, semiconductors, alloys and mixtures and combinations thereof, irrespective of their form, whether single crystalline, poly-crystalline or amorphous.

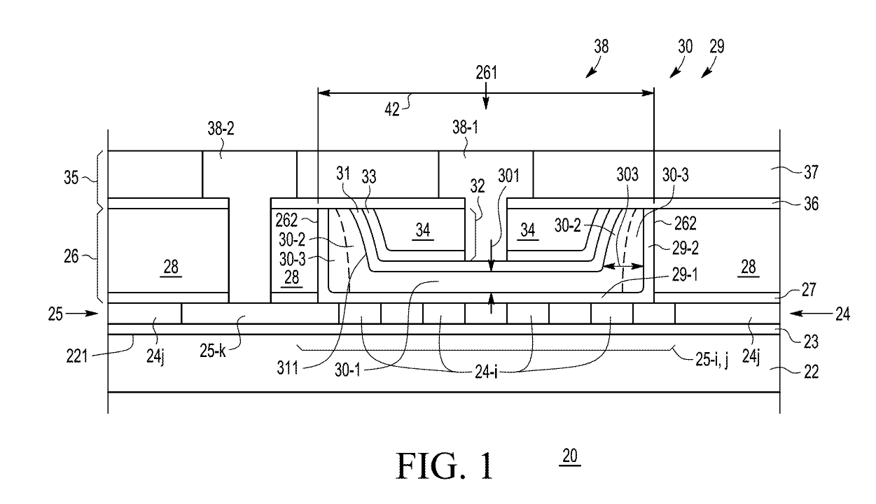

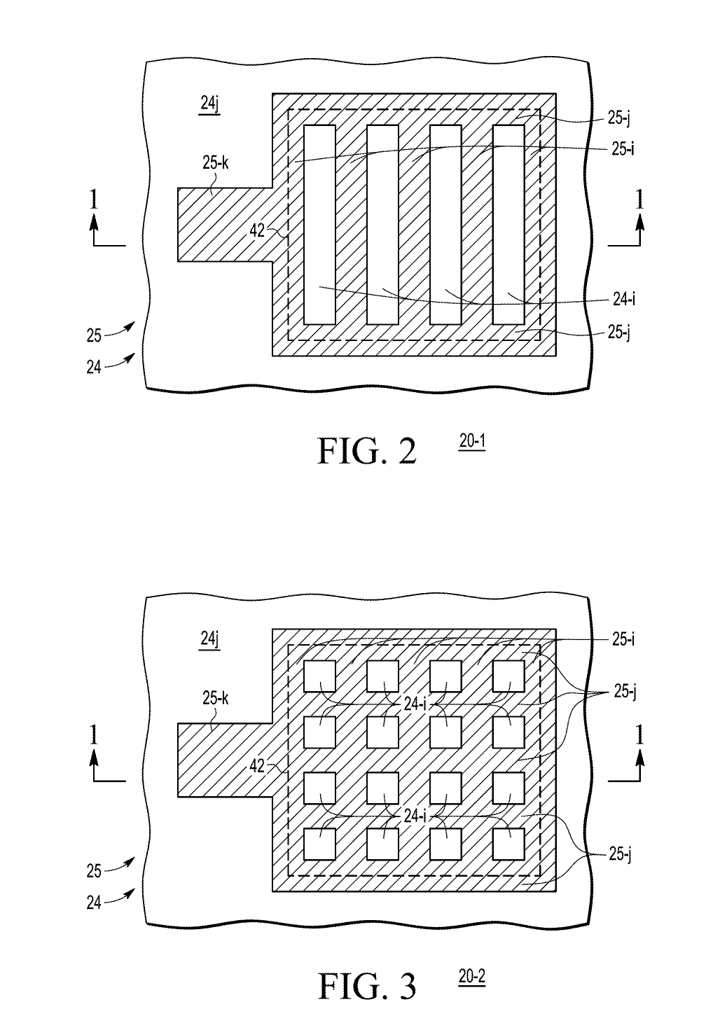

FIG. 1 shows a simplified schematic cross-sectional view of metal-insulator-metal (MIM) capacitor 20, according to an embodiment of the invention. Capacitor 20 comprises supporting substrate 22 having upper surface 221. Substrate 22 may be any type of material, conductive or non-conductive or a combination thereof. For convenience of description and not intended to be limiting, substrate 22 is assumed hereafter to comprise a stack of dielectric and semiconductor (SC) materials as might be used in the fabrication of an integrated circuit (IC) in which capacitor 20 can be incorporated. Persons of skill in the art will understand that while use of a dielectric-SC stack for substrate 22 may be desirable, it is not essential. Surface 221 of substrate 22 may have optional insulating layer 23. Layer 23 is useful when it is desirable to etch layer 23 differentially with respect to the surface region of substrate 22. Where the surface region of substrate 22 is for example, of silicon oxide, then silicon nitride is a non-limiting example of a useful material for layer 23, but other materials may also be used. In the example of FIG. 1, overlying surface 221 (and layer 23 when included) are regions 24, 25 (shown in plan view in FIGS. 2-4), where region 24 is an insulator and region 25 is a conductor. Reference number 24 refers collectively to regions 24i, 24j illustrated in FIGS. 1-13 and reference number 25 refers collectively to regions 25i, 25j, 25k of FIGS. 1-13. For convenience of description, conductor 25 is henceforth referred to as “metal” 25, and in a preferred embodiment may be metallic, but this is not essential. Metal 25 is also referred to as “capacitor bottom metal” 25 abbreviated as CBM 25 and forms one electrode of MIM capacitor 20.

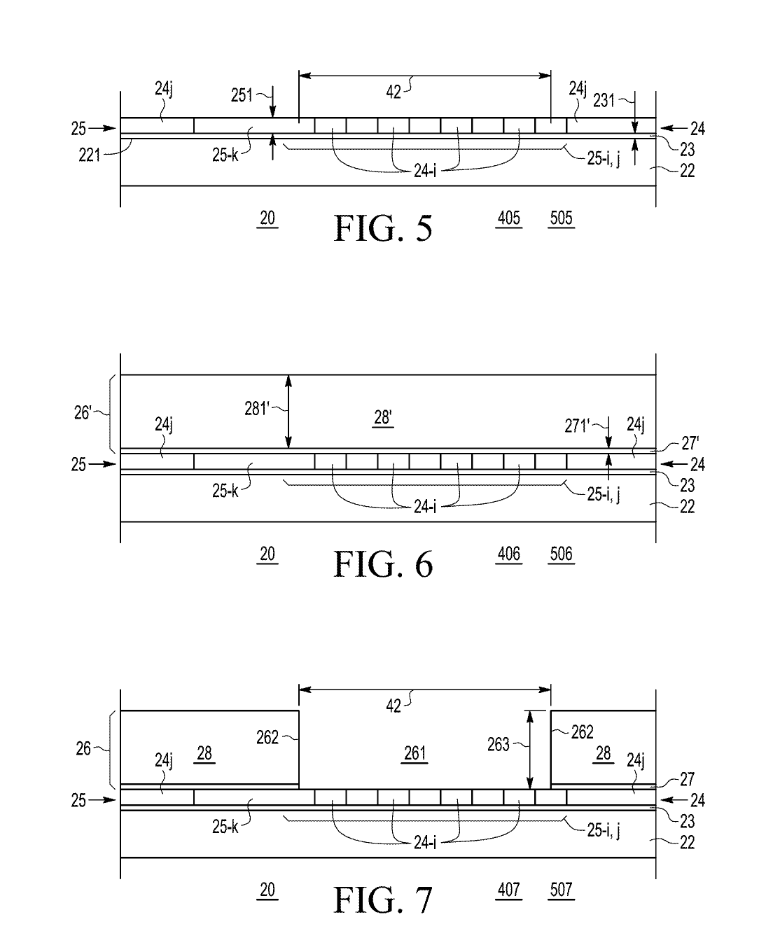

FIGS. 2-4 illustrate plan view arrangements 20-1, 20-2 and 20-3 of CBM 25 of MIM capacitor 20 of FIG. 1, according to further embodiments of the invention. For convenience of illustration, CBM 25 is hatched in FIGS. 2-4 to readily distinguish it from un-hatched insulator regions 24i within CBM 25 and regions 24j lying laterally outside CBM 25 CBM 25. FIG. 2 illustrates CBM 25 having a stripe-like configuration, wherein multiple relatively narrow metal stripes 25i are separated by stripe-like insulator regions 24i and laterally outside insulator region 24j (collectively 24). As is explained in more detail in connection with FIGS. 5-13, insulator regions 24 are conveniently of silicon oxide, but other organic or inorganic insulating materials may also be used. Metal stripes 25i are conveniently electrically tied together by cross conductors 25j and have external contact tab or region 25k. Conductors 25i, 25j, 25k are referred to collectively as conductors 25 or CBM 25.

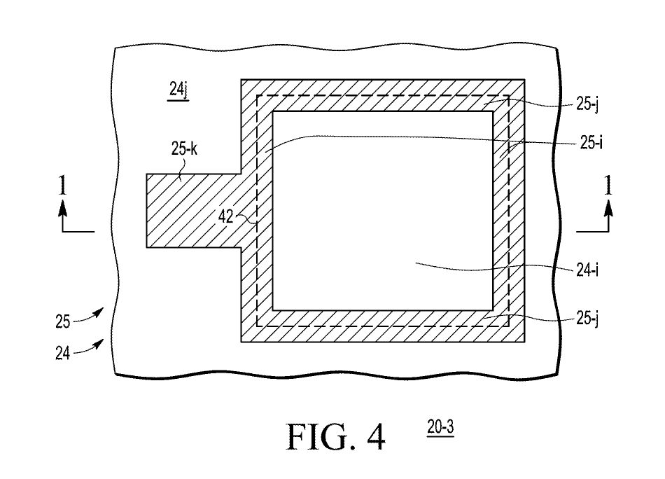

FIG. 3 illustrates CBM 25 having a mesh-like configuration, wherein multiple orthogonally arranged narrow metal stripes 25i, 25j have embedded therein multiple insulator regions 24i. Embedded regions 24i plus substantially surrounding insulator region 24j are referred to collectively as insulating or dielectric region 24. FIG. 4 illustrates CBM 25 having a frame-like configuration, wherein orthogonally arranged metal bars or stripes 25i, 25j form a frame-like shape surrounding central dielectric or insulator region 24i. Dielectric or insulator region 24j lies laterally outside CBM 25. CBM 25 conveniently has contact tab or portion 25k in FIGS. 2-4. The combination of conductor regions 25i, 25j and 25k are referred to collectively as CBM 25. While in a preferred embodiment, CBM 25 has the stripe-like arrangement of FIG. 2, the mesh-like arrangement of FIG. 3, or the frame-like arrangement of FIG. 4, this is merely illustrative of preferred arrangements and is not essential and CBM 25 may have any plan-view shape with conductive regions 25i, 25j of any shape and interspersed insulating region or regions 24i of any shape, including the arrangement where insulating regions 24i are omitted. Insulator or dielectric region 24j is also conveniently provided laterally outside of CBM 25 although that is not essential. The area density D_{A} of CBM 25 may be expressed as:

D_{A}=(Total metal area in CBM 25)/(Total area of CBM 25), Eq. 1

expressed as a percentage. The total metal area of CBM 25 equals the sum of the areas of metal regions 25i, 25j and 25k, that is, Total Metal Area=[(TA)₂₅ᵢ+(TA)₂₅ⱼ+(TA)₂₅ₖ] where the abbreviation “TA” stands for “total area of”. The total area of CBM 25 equals the total metal area plus the total area of intervening dielectric or insulating regions 24i, that is, the Total Area of CBM 25=[(TA)₂₅ᵢ+(TA)₂₅ⱼ+(TA)₂₅ₖ(TA)₂₄ᵢ], so that:

$${D}_{A} = \frac{[ {( TA )}_{25 i} + {( TA )}_{25 i} + {( TA )}_{25 k} ]}{[ {( TA )}_{25 i} + {( TA )}_{25 j} + {( TA )}_{25 k} + {( TA )}_{24 i} ]} . \qquad Eq . 2$$

It has been found that the manufacturing yield of MIM capacitor 20 is enhanced if D_{A} is less than 100%, preferably in the range of about 20%≦DA≦70%, but higher and lower values of D_{A} may also be used. For convenience of explanation, FIG. 1 and FIGS. 5-13 illustrate the arrangement of CBM 25 shown in plan view in FIGS. 2 and 3, but persons of skill in the art will readily understand how to modify FIGS. 1 and 5-13 when CBM 25 has the plan view shape illustrated in FIG. 4 or other plan view shapes.

Outline or perimeter 42 in FIGS. 1-4 shows the “footprint” of MIM capacitor 20 lying laterally within CBM 25. Referring again to FIG. 1, overlying CBM 25 and dielectric region 24j laterally outside of footprint 42 is dielectric 26. Dielectric 26 may be homogeneous or layered. In a preferred embodiment, dielectric 26 comprises initial dielectric layer or region 27 and overlying dielectric layer or region 28. When used, layer 27 is conveniently differentially etchable with respect to insulating region 24. Silicon nitride is a non-limiting example of a suitable material for dielectric layer or region 27. Overlying dielectric layer or region 27 is dielectric layer or region 28. In a preferred embodiment, dielectric layer or region 28 is differentially etchable with respect to layer or region 27, but this is not essential. Silicon oxide is a non-limiting example of a suitable material for dielectric layer or region 28. Cavity 261 having sidewall 262 is provided in dielectric 26. Cavity 261 has a lateral size and location corresponding to MIM capacitor footprint 42 and sidewall 262 of cavity 261 extends to CBM 25 where insulator regions 24i and some portions of conductor regions 25i, 25j are exposed within footprint 42. In the finished MIM capacitor, dielectric 26 occupies an area laterally outside of footprint 42 of MIM capacitor 20 and cavity 261.

Within cavity 261 over CBM 25 with insulator regions 24i and conductor regions 25i, 25j exposed within footprint 42 is barrier layer 29. Barrier layer 29 has first portion 29-1 overlying the exposed portions of CBM 25 with included or embedded insulator regions 24i and conductor regions 25i, 25j therein. Barrier layer 29 has second portion 29-2 lining sidewall 262 of cavity 261 in dielectric 26. Barrier layer 29 is an electrical conductor. (The composition of barrier layer 29 is described in more detail in connection with FIGS. 5-13.)

The purpose of barrier layer 29 is to: (i) inhibit or substantially prevent out-diffusion or migration of material from CBM 25 into overlying regions (e.g., into overlying capacitor dielectric 30); (ii) to increase the effective conductor area of CBM 25 to correspond to footprint 42 even when D_{A}<100% wherein footprint 42 overlies a combination of insulating regions 24i and conductor regions 25i, 25j laterally within footprint 42 of CBM 25; (iii) to increase the effective area of CBM 25 of MIM capacitor 20 by including the area of sidewall 262 of cavity 261 in insulator 26; and (iv) to avoid any electric field concentration regions within the overlying capacitor dielectric (e.g., dielectric 30) that can arise when D_{A}<100%. Such electric field concentration regions can arise at the joints where, for example, stripe-like or mesh-like or frame-like conductors 25i, 25j meet embedded dielectric regions 24i when the capacitor dielectric (e.g., dielectric 30) rests directly on such joints. Feature (i) provides improved long terms stability and reliability. Features (ii) and (iii) provide improved specific capacitance, that is, larger capacitance per unit (lateral) area of substrate 22 occupied by MIM capacitor 20. Feature (iv) avoids the failure mechanism that can be associated with electric field concentration regions in capacitor dielectric 30 if it rests directly on CBM 25, thereby improving the electrical properties and reliability of MIM capacitor 20. This is a very valuable combination of properties.

Overlying barrier layer 29 is capacitor dielectric 30. Capacitor dielectric 30 has portion 30-1 overlying barrier layer portion 29-1 above CBM 25 with conductors 25i, 25j and embedded dielectric regions 24i, and portion 30-2 overlying barrier layer portion 29-2 along sidewall 262 of cavity 261 of dielectric 26. In a preferred embodiment, sidewall portion 30-2 of capacitor dielectric 30 includes lateral dielectric spacer 30-3. The composition of capacitor dielectric 30 and the formation of spacer 30-3 are described in more detail in connection with FIGS. 5-14. Sidewall spacer 30-3 is desirable for reliability concerns but is not essential.

Overlying capacitor dielectric 30 is electrically conductive capacitor top electrode, e.g., capacitor top metal (CTM) 31, preferably of the same composition as barrier layer 29, although that is not essential. The specific capacitance of MIM capacitor 20 is maximized by providing a counter-electrode (e.g., CTM 31) facing barrier layer portion 29-2 on sidewalls 262 of cavity 261 as well as barrier layer portion 29-1 above footprint 42. These are desirable features.

Overlying CTM 31 is dielectric 32. In a preferred embodiment, dielectric 32 is desirably a differentially etchable double-layer, with portion 33 over CTM 31 and portion or region 34 overlying portion 33, but that is not essential. As explained in more detail in connection with FIGS. 5-13, layer 33 is conveniently silicon nitride and region 34 is conveniently silicon oxide, but other organic and/or inorganic insulator materials and combinations thereof may also be used. Other than electrical contacts to CBM 25 and CTM 31, MIM capacitor 20 is substantially completed.

To facilitate providing external electrical contacts 38 to MIM capacitor 20, dielectric 35 is provided overlying the above-described structure. Dielectric 35 is desirably but not essentially a differentially etchable double layer with first overlying layer 36, for example of silicon nitride, and second overlying layer 37, for example of silicon oxide, but other organic and/or inorganic insulator materials and combinations thereof may also be used. Electrical contact 38-1 is provided extending through dielectrics 35 and 32 to make electrical contact to CTM 31 and electrical contact 38-2 is provided extending through dielectric 35 and 26 to make electrical contact to CBM 25, e.g., on tab 25k. As will be understood by persons of skill in the art, further electrical contacts may be provided in order to connect MIM capacitor 20 to other elements of the IC of which it may form a part.

FIGS. 5-13 show simplified cross-sectional views of capacitor 20 of FIGS. 1-4 at various stages 405-413 of manufacture illustrating structures 505-513 formed in manufacturing stages 405-413, according to still further embodiments of the invention. In manufacturing stage 405 of FIG. 5, substrate 22 having upper surface 221 is provided, optionally having insulating surface layer 23 thereon. Where substrate 22 comprises a dielectric-silicon semiconductor stack, layer 23 is conveniently of silicon nitride with thickness 231 usefully in the range of about 10-100 nanometers, preferably about 50 nanometers, but thicker or thinner layers and other materials may also be used.

Structure 505 of FIG. 5 may be formed in at least two ways. According to one embodiment, conductor layer 25 is deposited on substrate 22 (with layer 23 if used), masked and etched and then covered by dielectric layer 24 and the combination planarized resulting in structure 505 of FIG. 5. In another embodiment, dielectric layer 24 is deposited first, masked and etched in locations where conductor regions 25i, 25j, 25k are desired, then metal layer 25 is applied filling the voids created in dielectric layer 24 in locations 25i, 25j, 25k and the combination planarized resulting in structure 505 of FIG. 5, with the latter arrangement being preferred. Chemical mechanical polishing (CMP) is a suitable planarization technique, but other well known planarization techniques may also be used. In either case, overlying substrate 22 (and layer 23 when present) is CBM 25 of thickness 251 and with the desired pattern of conductor regions 25i, 25j and 25k, such as are illustrated in FIGS. 2-4 and variations thereof. The area density D_{A} of CBM 25 is determined by the masking operation that determines the area and location of metal regions 25i, 25j, 25k and intervening embedded dielectric regions 24i. CBM 25 is conveniently of high conductivity metallic material. Cu, Al, and Al(5%)Cu, are non-limiting examples of suitable conductor materials, but other metallic and non-metallic conductors may also be used. Cu is preferred. Persons of skill in the art will understand how to choose thickness 251 of conductor 25 to suit their particular application. Layer 24 is conveniently of silicon oxide, but other organic or inorganic dielectrics may also be used. Structure 505 results. While CBM 25 is shown in FIGS. 2-4 as having a substantially rectangular outer plan view shape or perimeter, this is merely for convenience of explanation and not intended to be limiting. Persons of skill in the art will understand that CBM 25 may have any plan view shape or perimeter. Non-limiting examples are circular, elliptical, polygonal, and combinations thereof, etc., and individual elements 24i, 24j, 25i, 25j, 25k may also have any plan view shape.

Referring now to manufacturing stage 406 of FIG. 6, dielectric layer 26′ is provided overlying structure 505, where the 0 indicates that such layer is the precursor to layer 26 of FIG. 1. Layer 26′ may be layered or homogeneous. In a preferred embodiment, layer 26′ comprises initial layer 27′ followed by upper layer 28′, again with the 0 indicating that such layers are the precursors to regions or layers 27, 28 of FIG. 1, but other arrangements may also be used. Layer 27′ is conveniently of silicon nitride with thickness 271′ in the range of about 10-100 nanometers, preferably about 50 nanometers, but thicker or thinner layers and other dielectric materials may also be used. In a preferred embodiment, dielectric layer 28′ of thickness 281′ overlies layer 27′. Layer 28′ is conveniently of silicon oxide with thickness 281′ in the range of about 200-1500 nanometers, preferably about 800 nanometers, but thicker or thinner layers and other dielectric materials may also be used. Layer 28′ is conveniently formed using conventional tetra-ethyl-ortho-silicate (TEOS) deposition, but other well known dielectric formation techniques may also be used. Structure 506 results.

Referring now to manufacturing stage 407 of FIG. 7, structure 506 is conventionally masked and etched to form cavity 261 in dielectric layer 26′ with sidewall 262. Cavity 261 has lateral extent 42 corresponding to foot print 42 of MIM capacitor 20 (see FIGS. 1-4). Portions 25i, 25j of CBM 25 and embedded dielectric regions 24i lying laterally within MIM capacitor footprint 42 are exposed in cavity 261. This masking step is the only additional masking step needed to form MIM capacitor 20 beyond those otherwise already available in a typical IC manufacturing process, thereby minimizing the added expense of providing MIM capacitor 20. Structure 507 results.

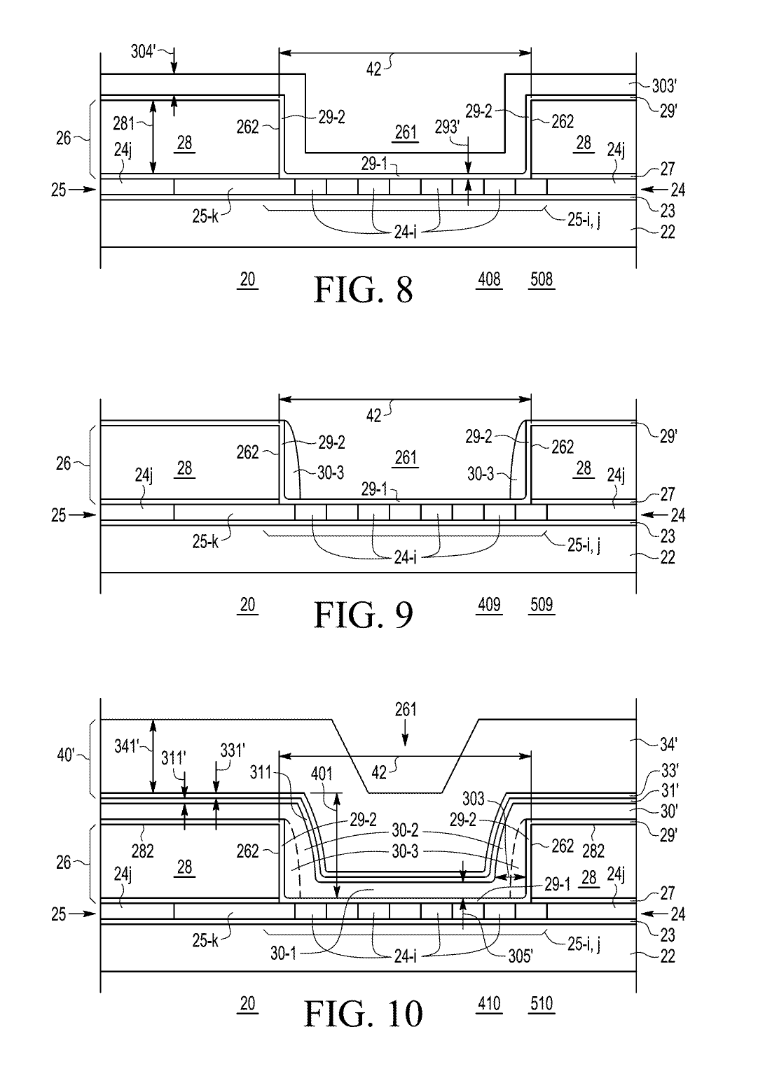

Referring now to manufacturing stage 408 of FIG. 8, electrically conductive barrier layer 29′ of thickness 293′ is deposited over structure 507, followed by dielectric layer 303′ of thickness 304′ overlying barrier layer 29′. Barrier layer 29′ and dielectric layer 303′ extend into cavity 261. Barrier layer 29′ has portion 29-1 in contract with conductor regions 25i, 25j of CBM 25 and embedded dielectric regions 24i. Barrier layer 29′ has portion 29-2 on sidewall 262 of cavity 261. Any reasonably conductive material may be used for barrier layer 29′ provided that it can also inhibit significant out-diffusion or migration of the material of CBM 25 into overlying regions, e.g., into overlying capacitor dielectric 30. Where CBM 25 comprises Cu or other relatively mobile electrically conductive materials, Ta, Al (5%)Cu and TiN, and combinations thereof are non-limiting examples of suitable materials for barrier layer 29′ but other electrically conductive materials may also be used. Ta is preferred. Thickness 293′ is conveniently in the range of about 10-200 nanometers, preferably about 50 nanometers, but thicker or thinner layers may also be used. Silicon oxide, silicon nitride, silicon oxy-nitride and combinations thereof are non-limiting examples of suitable materials for dielectric layer 303′ but other insulating materials may also be used. Silicon nitride is preferred. Thickness 304′ is conveniently in the range of about 5 to 50 percent of thickness 281 of layer 28, preferably about 20 percent, but thicker or thinner layers may also be used. The material of dielectric layer 303′ is used to form sidewall spacers 30-3 of FIG. 1 and is desirably differentially etchable with respect to the material of barrier layer 29′. Structure 508 results.

Referring now to manufacturing stage 409 of FIG. 9, structure 508 is anisotropically etched to remove dielectric material 303′ of FIG. 8 substantially everywhere except along sidewalls 29-2 of barrier layer 29 on sidewall 262 of cavity 261, thereby leaving in place sidewall spacers 30-3 against barrier layer sidewall 29-2, while barrier layer portion 29-1 is exposed in cavity 261. Such anisotropic etching is well known in the art. Structure 509 results.

Referring now to manufacturing stage 410 of FIG. 10, structure 509 desirably but not essentially has a succession of various further layers formed thereon, layer 30′ of thickness 305′, layer 31′ of thickness 311′, layer 33′ of thickness 331′, and layer 34′ of thickness 341′, where the (′) indicates that such layers are the precursors to similarly identified layers or regions in FIG. 1 without the prime (′). Layer 30′ is intended to form capacitor dielectric regions 30-1 and 30-2. Silicon nitride, silicon oxide, silicon oxynitride, and other comparatively high-permittivity materials are non-limiting examples of suitable materials for capacitor dielectric regions 30-1, 30-2, where silicon nitride is preferred, but other organic or inorganic or combinations of dielectric materials may also be used. The choice of thickness 305′ will depend upon the desired voltage tolerance and capacitance per unit area sought by the designer and is within the competence of persons of skill in the art. Layer 31′ is an electrical conductor intended to form capacitor top metal (CTM) 31 of FIG. 1 and conveniently is of the same composition and thickness as barrier layer 29′ but other materials and thicker or thinner layers may also be used. The choice of material for CTM layer 31′ is within the competence of person of skill in the art. Portion 31 (see FIG. 1) of layer 31′ that remains in cavity 261 when capacitor 20 is finished, also serves as CTM 31 of MIM capacitor 20.

Overlying CTM layer 31′ is dielectric layer 40′. Layer 40′ may be homogeneous or layered. In a preferred embodiment, dielectric layer 40′ comprises first layer 33′ of thickness 331′ surmounted by second dielectric layer 34′ of thickness 341′. Silicon nitride, silicon oxide, and silicon oxy-nitride are non-limiting examples of suitable materials for dielectric layer 33′. Silicon nitride is preferred, but other organic or inorganic or combinations of dielectric materials may also be used. Thickness 331′ is usefully in the range of about 10 to 100 nanometers, with about 50 nanometers being preferred but thicker or thinner layers may also be used. Silicon oxide, silicon nitride, and silicon oxy-nitride are non-limiting examples of suitable materials for dielectric layer 34′. Silicon oxide is preferred, but other organic or inorganic or combinations of dielectric materials may also be used. Thickness 341′ is usefully in the range of about 200 to 2000 nanometers, with about 1000 nanometers being preferred, but thicker or thinner layers may also be used. Structure 510 results. In general, thickness 341′ is adjusted so that thickness 401 equals or exceeds depth 263 of cavity 261 (e.g., see FIG. 7), so that when structure 510 is subsequently planarized, little or no void is left in the location of cavity 261.

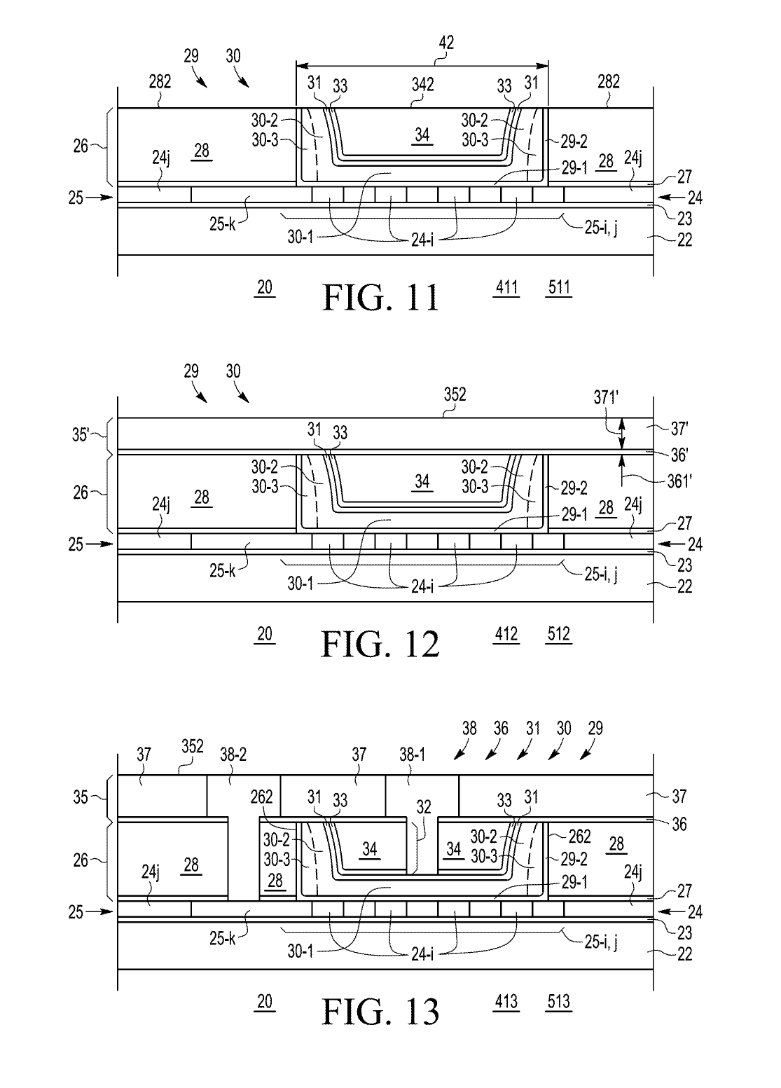

Referring now to manufacturing stage 411 of FIG. 11, structure 510 is planarized, to remove those portions of layers 29′, 30′, 31′, 33′ overlying substrate 22 above surface 282. CMP is a suitable planarization technique, but other well known planarization techniques or combinations thereof may also be used. In a preferred embodiment, a brief wet etch is used following CMP to remove any residue of CTM 31 and of first barrier layer 29, but this is not essential. Such brief wet etch is believed to aid in reducing subsequent leakage through capacitor dielectric 30. Structure 511 results. Other than providing external connection thereto, the internal structure of MIM capacitor 20 is substantially finished.

Referring now to manufacturing stage 412 of FIG. 12, structure 511 is covered by dielectric layer 35′ having upper surface 352. Dielectric layer 35′ may be homogeneous or layered. In a preferred embodiment, dielectric layer 35′ comprises first layer 36′ of thickness 361′ surmounted by second dielectric layer 37′ of thickness 371′. Silicon nitride, silicon oxide, and silicon oxy-nitride are non-limiting examples of suitable materials for dielectric layer 36′. Silicon nitride is preferred, but other organic or inorganic dielectrics or combinations of dielectric materials may also be used. Thickness 361′ is usefully in the range of about 10 to 100 nanometers, with about 50 nanometers being preferred but thicker or thinner layers may also be used. Silicon oxide, silicon nitride, and silicon oxy-nitride are non-limiting examples of suitable materials for dielectric layer 37′. Silicon oxide is preferred, but other organic or inorganic dielectrics or combinations of dielectric materials may also be used. Thickness 371′ is usefully in the range of about 100 to 1000 nanometers, with about 350 nanometers being preferred but thicker or thinner layers may also be used. Structure 512 results.

Referring now to manufacturing stage 413 of FIG. 13, upper surface 352 of dielectric layer 35 is masked so that appropriate vias can be etched and then refilled with conductor 38 to provide connection 38-1 through dielectric layers or regions 37, 36, 34 and 33 to CTM 31, and to provide connection 38-2 through dielectric layers or regions 37, 36, 28 and 27 to CBM 25 via tab or portion 25k. Structure 513 results, which is also substantially illustrated in FIGS. 1-4. As will be understood by those of skill in the art, further interconnections can be provided to connect MIM capacitor 20 of FIGS. 1-4, and 13 to other portions of the IC of which it is a part. Such interconnections are conventional. The above-described manufacturing stages are adapted to provide MIM capacitor 20, that:

(a) Improves long term stability by inhibiting deleterious out-diffusion of materials of CBM 25 into capacitor dielectric 30 by use of barrier layer 29;

(b) Has maximum capacitance per unit occupied area by having portion 29-1 of barrier layer 29 extend over dielectric regions 24i when CBM 25 has area density D_{A}<100% and by extending the effective size of CBM 25 by having portion 29-2 of conductive barrier layer 29 extend up sidewall 262 of cavity 261 and by having the counter electrode of MIM capacitor 20 formed by CTM 31 also face sidewall 262;

(c) Improves manufacturing yield by using striped, meshed or frame-like (open bottom) metal structure for CBM 25 where D_{A}<100%. This is important for copper backend processes wherein the area density D_{A} of CBM 25 can have an important impact on CMP uniformity.

(d) Improves manufacturing yield and device's reliability as well as MIM capacitor properties by minimizing electric field concentration and the failure mechanisms that can arise therefrom, especially where D_{A}<100%, by having lower barrier layer 29-1 cover the joints between conductors 25i, 25j and interspersed dielectric regions 24i.

(e) Further improves manufacturing yield and device reliability by providing additional lateral dielectric spacer 30-3 where conductive barrier layer portion 29-2 on sidewall 262 joins conductor portion 29-1 on footprint 42;

(f) Minimizes the additional cost of providing MIM capacitors by adding only one further masking operation beyond what is already present in the typical IC manufacturing process; and

(g) Maximizes the attainable capacitance per unit occupied area.

These are significant advantages facilitating incorporation of MIM capacitors 20 into modern ICs.

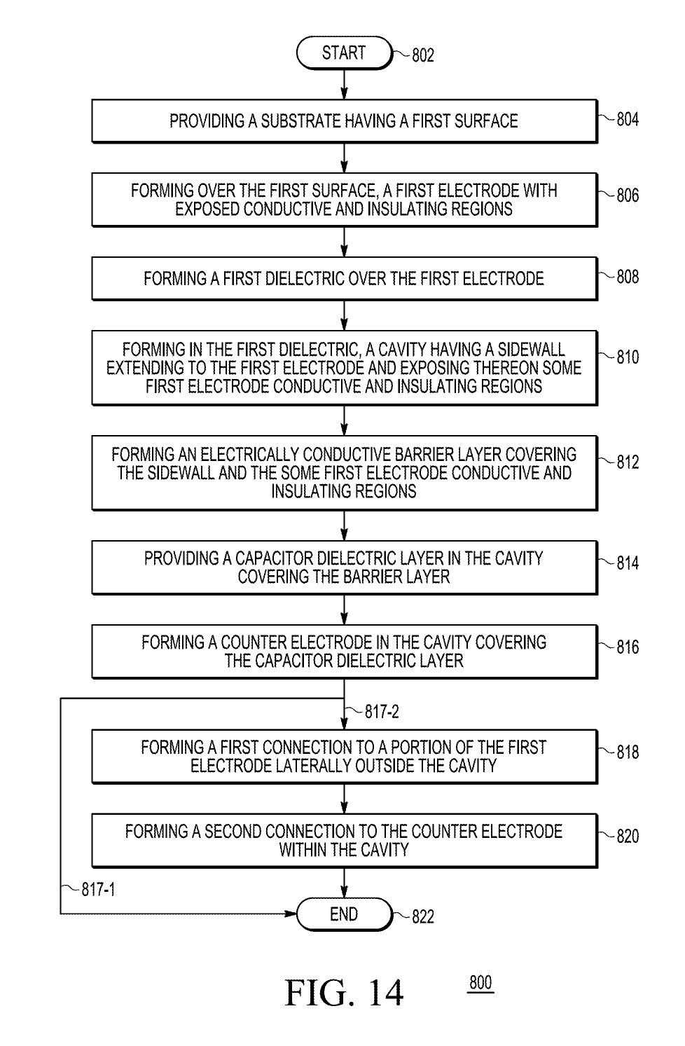

FIG. 14 illustrates a flow chart for a method 800 of manufacturing MIM capacitor 20 as a part of an IC, according to a yet further embodiment of the invention. Method 800 begins with start 802 and initial step 804 wherein there is provided a substrate (22) having a first surface (221). In step 806, there is formed over the first surface (221) a first electrode (CBM 25) with exposed conductive (25i, 25j) and insulating (24i) regions. In step 808, a first dielectric (26) is formed over the first electrode (CBM 25). In step 810, a cavity (261) is formed in the first dielectric (26) having a sidewall (262) extending to the first electrode (CBM 25) and exposing thereon some first electrode conductive (25i, 25j) and insulating (24i) regions. In step 812, an electrically conductive barrier layer (29) is formed (e.g., with portion 29-2) covering the sidewall (262) and (e.g., with portion 29-1) covering the some first electrode conductive (25i, 25j) and insulating (24i) regions. In step 814 there is provided a capacitor dielectric layer (30) in the cavity (261) covering the barrier layer (29). In step 816, a counter electrode (31) is formed in the cavity (261) covering the capacitor dielectric layer (30). In a first embodiment, method 800 then proceeds along path 817-1 to END (822). In a second embodiment, method 800 then proceeds along path 817-2 to step 818 wherein there is formed a first connection (38-2) to a portion (25k) of the first electrode (CBM 25) laterally outside the cavity (261). In step 820 there is formed a second connection (38-1) to the counter electrode (31) within the cavity (261). According to this embodiment, method 800 then proceeds to END (822).

According to still further embodiments: step 806 may include forming a first electrode (CBM 25) having an area density D_{A} less than 100%; step 806 may include forming a first electrode (CBM 25) having conductive regions (25i, 25j) and interspersed dielectric regions (24i); step 806 may include forming a first electrode ((CBM 25) having stripe-like or mesh-like or frame-like conductive regions (25i, 25j) with one or more interspersed dielectric regions (24i). According to another further embodiment, step 814 may include forming a spacer (30-3) on the conductive barrier layer portion (29-2) on sidewall (262) of the cavity (261) as a part of providing the capacitor dielectric (30) covering the barrier layer (29). According to a yet further embodiment, step 808 may comprise forming the first dielectric (26) as a double layer, with a first insulating layer (27), and a second insulating layer (28) differentially etchable with respect to the first insulating layer. According to another embodiment, step 806 may include forming a copper containing first electrode (CBM 25) and step 812 may include forming a Ta or other electrically conductive material barrier layer (29). According to yet another embodiment, step 816 may further include covering the counter electrode (CTM 31) with an additional dielectric layer (32), which additional dielectric layer (32) is penetrated in step 820 during forming of the second connection (38-1).

According to a first embodiment, there is provided a method (800) for forming a metal-insulator-metal (MIM) capacitor (20), comprising, providing a substrate (22) having a first surface (221), forming over the first surface (221) a first electrode (25) with exposed conductive (25i, 25j) and insulating (24i) regions, forming a first dielectric (26) over the first electrode (25), forming in the first dielectric (26) a cavity (261) having a sidewall (262) extending to the first electrode (25) and exposing thereon at least some of the first electrode (25) conductive (25i, 25j) and insulating (24i) regions, forming an electrically conductive barrier layer (29) covering the sidewall (262) and the some of the first electrode (25) conductive (25i, 25j) and insulating (24i) regions, providing a capacitor dielectric layer (30) in the cavity (261) covering the electrically conductive barrier layer (29), and forming a counter electrode (31) in the cavity (261) covering the capacitor dielectric layer (30). According to a further embodiment, the step of forming the first electrode (25) comprises forming a first electrode (25) with an area density D_{A} less than 100 percent. According to a yet further embodiment, the step of forming the exposed conductive (25i, 25j) and insulating (24i) regions comprises forming the exposed conductive (25i, 25j) and insulating (24i) regions having a stripe-like plan view configuration (20-1). According to a still yet further embodiment, the step (806) of forming the exposed conductive (25i, 25j) and insulating (24i) regions comprises forming the exposed conductive (25i, 25j) and insulating (24i) regions having a mesh-like plan view configuration (20-2). According to a yet still further embodiment, the step (806) of forming the exposed conductive (25i, 25j) and insulating (24i) regions comprises forming the exposed conductive (25i, 25j) and insulating (24i) regions having a frame-like plan view configuration (20-3). According to another embodiment, the step (806) of forming the first electrode (25) comprises forming a first electrode containing copper and the step (812) of forming the electrically conductive barrier layer (29) comprises forming an electrically conductive barrier layer containing Ta, Al (5%)Cu, or TiN or a combination thereof. According to a still another embodiment, the step (810) of forming the cavity (261) defines a lateral footprint (42) of the MIM capacitor (20). According to a yet another embodiment, the step (806) of forming the first electrode (25) comprises planarizing the conductive (25i, 25j, 25k) and insulating (24i) regions thereof. According to a still yet another embodiment, the step (814) of providing a capacitor dielectric layer (30) in the cavity (261) covering the electrically conductive barrier layer (29), comprises, forming a dielectric spacer (30-3) on an electrically conductive barrier layer region (29-2) on the sidewall (262) of the cavity (261). According to a yet still another embodiment, the step (808) of forming a first dielectric (26) over the first electrode (25), comprises, forming the first dielectric (26) as a double layer with a first insulating layer (27), and with a second insulating layer (28), substantially differentially etchable with respect to the first insulating layer (27). According to a further another embodiment, the step (816) of forming a counter electrode (31) in the cavity (261) covering the capacitor dielectric layer (30), further comprises, covering the counter electrode (31) with an additional dielectric layer (32). According to a still further another embodiment, the step (820) of forming a second connection (38-1) to the counter electrode (31) within the cavity (261), further comprises, penetrating the additional dielectric layer (32) during forming of the second connection (38-1). According to a yet further another embodiment, the method further comprises after the step (816) of forming the counter electrode (31), planarizing the MIM capacitor (20) before forming the second connection (38-1).

According to a second embodiment, there is provided a metal-insulating-metal (MIM) capacitor, comprising, a first electrode (25) with conductive (25i, 25j) and insulating (24i) regions, a first dielectric (26) over the first electrode (25) with a cavity location (261) therein having a sidewall (262) extending to the first electrode (25) wherein some conductive (25i, 25j) and insulating (24i) regions face into the cavity location (261), an electrically conductive barrier layer (29) covering the sidewall (262) and the some of the conductive (25i, 25j) and insulating (24i) regions, a capacitor dielectric layer (30) in the cavity location (261) covering the electrically conductive barrier layer (29), and a counter electrode (31) in the cavity location (261) covering the capacitor dielectric layer (30). According to a further embodiment, the MIM capacitor further comprises a first external connection (38-2) extending to a portion (25k) of the first electrode (25) laterally outside the cavity location (261), and a second connection (38-1) extending to the counter electrode (31) within the cavity location (261). According to a still further embodiment, the electrically conductive barrier layer (29) is substantially resistant to migration of material of the first electrode (25) into the capacitor dielectric layer (30). According to a yet further embodiment, the counter electrode (31) has a sidewall (311) facing the sidewall (262) of the cavity location (261). According to a still yet further embodiment, between a sidewall (311) of the counter electrode (31) and the electrically conductive barrier layer (29) on the sidewall (262) of the cavity location (261) is a dielectric spacer (30-3) and capacitor dielectric (30-2) of width (303) greater than a thickness (301) of a portion (30-1) of the dielectric spacer (30) overlying a portion of (29-1) of the electrically conductive barrier layer (29) immediately above the first electrode (25). According to a yet still further embodiment, the first electrode (25) has an area density D_{A} less than 100%.

According to a third embodiment, there is provided a method (800) for forming a metal-insulator-metal (MIM) capacitor (20), comprising, providing a substrate (22) having a first surface (221) on which is a first electrode (25) with exposed conductive (25i, 25j) and insulating (24i) regions, forming a first dielectric (26) over the first electrode (25), the first dielectric (26) having a cavity (261) therein with a sidewall (262) extending to the first electrode (25) so that at least some of the first electrode (25) conductive (25i, 25j) and insulating (24i) regions are exposed in the cavity (261), forming an electrically conductive barrier layer (29) having a sidewall portion (29-2) covering the sidewall (262) and another portion (29-1) covering the exposed first electrode (25) conductive (25i, 25j) and insulating (24i) regions, providing a capacitor dielectric layer (30) on the barrier layer (29) having a first thickness (301) over the exposed first electrode (25) conductive (25i, 25j) and insulating (24i) regions and a second larger thickness (303) on the sidewall portion (29-2) of the electrically conductive barrier layer (29), and forming a counter electrode (31) on the capacitor dielectric layer(30).

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described and methods of preparation in an exemplary embodiment without departing from the scope of the invention as set forth in the appended claims and their legal equivalents.

What is claimed is:

1. A method or forming a metal-insulator-metal (MIM) capacitor, comprising:
providing a substrate having a first surface;
forming over the first surface a first electrode with exposed conductive and insulating regions;
forming a first dielectric over the first electrode;
forming in the first dielectric a cavity having a sidewall extending to the first electrode and exposing thereon at least some of the first electrode conductive and insulating regions;
forming an electrically conductive barrier layer covering the sidewall and the some of the first electrode conductive and insulating regions;
providing a capacitor dielectric layer in the cavity covering the electrically conductive barrier layer; and
forming a counter electrode in the cavity covering the capacitor dielectric layer.

2. The method of claim 1, wherein the step of forming the first electrode comprises forming a first electrode with an area density D_{A} less than 100 percent.

3. The method of claim 2, wherein the step of forming the exposed conductive and insulating regions comprises forming the exposed conductive and insulating regions having a stripe-like plan view configuration.

4. The method of claim 2, wherein the step of forming the exposed conductive and insulating regions comprises forming the exposed conductive and insulating regions having a mesh-like plan view configuration.

5. The method of claim 2, wherein the step of forming the exposed conductive and insulating regions comprises forming the exposed conductive and insulating regions wherein the exposed conductive regions have a frame-like plan view configuration substantially surrounding at least one insulating region.

6. The method of claim 1, wherein the step of forming the first electrode comprises forming a first electrode containing copper and the step of forming the electrically conductive barrier layer comprises forming an electrically conductive barrier layer containing Ta, Al (5%)Cu, TiN or a combination thereof.

7. The method of claim 1, wherein the step of forming the cavity defines a lateral footprint of the MIM capacitor.

8. The method of claim 1, wherein the step of forming the first electrode comprises planarizing the conductive and insulating regions thereof.

9. The method of claim 1, wherein the step of providing a capacitor dielectric layer in the cavity covering the electrically conductive barrier layer, comprises, forming a dielectric spacer on an electrically conductive barrier layer region on the sidewall of the cavity.

10. The method of claim 1, wherein the step of forming a first dielectric over the first electrode, comprises, forming the first dielectric as a double layer with a first insulating layer, and with a second insulating layer, substantially differentially etchable with respect to the first insulating layer.

11. The method of claim 2, wherein the step of forming a counter electrode in the cavity covering the capacitor dielectric layer, further comprises, covering the counter electrode with an additional dielectric layer.

12. The method of claim 12, wherein the step of forming a second connection to the counter electrode within the cavity, further comprises, penetrating the additional dielectric layer during forming of the second connection.

13. The method of claim 1, further comprising after the step of forming the counter electrode, planarizing the MIM capacitor before forming the second connection.

14. A metal-insulator-metal (MIM) capacitor comprising:
a first electrode with conductive and insulating regions;
a first dielectric over the first electrode with a cavity location herein having a sidewall extending to the first electrode wherein some conductive and insulating regions face into the cavity location;
an electrically conductive barrier layer covering the sidewall and the some of the conductive and insulating regions;
a capacitor dielectric layer in the cavity location covering the electrically conductive barrier layer; and
a counter electrode in the cavity location covering the capacitor dielectric layer.

15. The capacitor of claim 14, further comprising:
a first external connection extending to a portion of the first electrode laterally outside the cavity location; and
a second connection extending to the counter electrode within the cavity location.

16. The capacitor of claim 14, wherein the electrically conductive barrier layer is substantially resistant to migration of material of the first electrode into the capacitor dielectric layer.

17. The capacitor of claim 14, wherein the counter electrode has a sidewall facing the sidewall of the cavity location.

18. The capacitor of claim 17, wherein between a sidewall of the counter electrode and the electrically conductive barrier layer on the sidewall of the cavity location is a dielectric spacer and capacitor dielectric of combined lateral width greater than a thickness of a portion of the dielectric spacer overlying a portion of the electrically conductive barrier layer immediately above the first electrode.

19. The capacitor of claim 14, wherein a first electrode has an area density D_{A} less than 100%.

20. A method for forming a metal-insulator-metal (MIM) capacitor, comprising:
providing a substrate having a first surface on which is a first electrode with exposed conductive and insulating regions;
forming a first dielectric over the first electrode, the first dielectric having a cavity therein with a sidewall extending to the first electrode so that at least some of the first electrode conductive and insulating regions are exposed in the cavity;
forming an electrically conductive barrier layer having a sidewall portion covering the sidewall and another portion covering the exposed first electrode conductive and insulating regions;
providing a capacitor dielectric layer on the barrier layer having a first thickness over the exposed first electrode conductive and insulating regions and a second larger thickness on the sidewall portion of the electrically conductive barrier layer; and
forming a counter electrode on the capacitor dielectric layer.
